(19) United States
(12) Patent Application Publication
(10) Pub. No.: US 2006/0163731 A1
(43) Pub. Date: Jul. 27, 2006

(54) Dual damascene interconnections employing a copper alloy at the copper/barrier interface

(76) Inventor: Keishi Inoue, Mount Kisco, NY (US)

Correspondence Address: MAYER & WILLIAMS PC, 251 NORTH AVENUE WEST, 2ND FLOOR, WESTFIELD, NJ, 07090, US

(21) Appl. No.: 11/040,865

(22) Filed: Jan. 21, 2005

(51) Int. Cl. H01L 23/52; H01L 21/4763

(52) U.S. Cl. 257/751; 257/762; 438/687; 438/638; 438/643

(57) ABSTRACT

A method of fabricating a dual damascene interconnection is provided. The method begins by forming on a substrate a dielectric layer and forming a via in the dielectric layer. The dielectric layer is partially etched to form a trench, which is connected to the via and in which interconnections will be formed. A barrier layer is formed that overlies the via and the trench. A copper alloy layer is formed that overlies the barrier layer. The interconnections are completed by filling the trench and the via with copper.

### FIELD OF THE INVENTION

The present invention relates generally to dual damascene interconnections for integrated circuits, and more specifically to a dual damascene interconnection in which the conductive material that is employed adheres in a reliable manner to the barrier layer that contacts the dielectric layer.

### BACKGROUND OF THE INVENTION

The manufacture of integrated circuits in a semiconductor device involves the formation of a sequence of layers that contain metal wiring. Metal interconnects and vias which form horizontal and vertical connections in the device are separated by insulating or dielectric materials to prevent crosstalk between the metal wiring that can degrade device performance. A popular method of forming an interconnect structure is a dual damascene process in which vias and trenches are filled with metal in the same step to create multi-level, high density metal interconnections needed for advanced high performance integrated circuits. The most frequently used approach is a via first process in which a via is formed in a dielectric layer and then a trench is formed above the via. Recent achievements in dual damascene processing include lowering the resistivity of the metal interconnect by switching from aluminum to copper, decreasing the size of the vias and trenches with improved lithographic materials and processes to improve speed and performance, and reducing the dielectric constant (k) of insulating materials to avoid capacitance coupling between the metal interconnects.

When copper is employed as the metal for the interconnects a number of problems arise. For example, copper is known to diffuse through certain of the low-k dielectric materials that have recently been employed to reduce both RC delays and power consumption. As a result, a barrier layer is sometimes used between the dielectric and the copper to prevent diffusion of copper through the dielectric material. Unfortunately, copper does not adhere well to many of the materials from which the barrier layer is formed. As a consequence the reliability of the resulting device may be severely compromised.

Accordingly, it would be desirable to provide a dual damascene interconnect in which the conductive material that is employed adheres in a reliable manner to the barrier layer that contacts the dielectric layer.

### SUMMARY OF THE INVENTION

In accordance with the present invention, a method of fabricating a dual damascene interconnection is provided. The method begins by forming on a substrate a dielectric layer and forming a via in the dielectric layer. The dielectric layer is partially etched to form a trench, which is connected to the via and in which interconnections will be formed. A barrier layer is formed that overlies the via and the trench. A copper alloy layer is formed that overlies the barrier layer. The interconnections are completed by filling the trench and the via with copper.

In accordance with one aspect of the invention, a metal other than copper is deposited on the barrier layer. After the interconnections are completed, an anneal is performed to thereby form the copper alloy layer by interdiffusion of copper and the metal.

In accordance with another aspect of the invention, the metal other than copper is selected from the group consisting of Al, Ti, Sn and Ag.

In accordance with another aspect of the invention, the copper alloy is selected from the group consisting of a CuAl alloy, CuTi alloy, CuSn alloy and a CuAg alloy.

In accordance with another aspect of the invention, the metal other than copper is deposited by sputtering.

In accordance with another aspect of the invention, the barrier layer is selected from the group consisting of tantalum, tantalum nitride, titanium, titanium silicide or zircuonium.

In accordance with another aspect of the invention, a lower interconnection is formed on the substrate and an etch stop layer is formed on the lower interconnection.

In accordance with another aspect of the invention, the etch stop layer is formed of at least one of SiC, SiN, and SiCN.

In accordance with another aspect of the invention, the dielectric layer is an organo silicate glass layer.

In accordance with another aspect of the invention, the dielectric layer is formed using chemical vapor deposition.

In accordance with another aspect of the invention, a capping layer is formed on the dielectric layer and the via is formed in the capping layer and the dielectric layer.

In accordance with another aspect of the invention, the capping layer is formed of at least one of SiO₂, SiOF, SiON, SiC, SiN and SiCN.

In accordance with another aspect of the invention, a photoresist pattern is formed on the copper layer to define the via. The copper layer and the dielectric layer are dry etched using the photoresist pattern as an etch mask.

In accordance with another aspect of the invention, a trench photoresist pattern is formed over the dielectric layer to define the trench. The trench is formed by dry etching using the trench photoresist pattern as an etch mask.

In accordance with another aspect of the invention, the trench photoresist pattern in formed on the capping layer.

In accordance with another aspect of the invention, the dry etching uses CₓF_{y} or CₓH_{y}F_{z} as a main etching gas. The photoresist pattern is removed using an H₂-based plasma.

In accordance with another aspect of the invention, the dielectric is a hybrid low-k dielectric material.

In accordance with another aspect of the invention, an integrated circuit is provided that has at least one dual damascene interconnection constructed in accordance with the aforementioned method.

### BRIEF DESCRIPTION OF THE DRAWINGS

FIGS. 1-9 show cross-sectional views illustrating the formation of a dual damascene structure constructed in accordance with the present invention.

### DETAILED DESCRIPTION

The methods and structures described herein do not form a complete process for manufacturing semiconductor device structures. The remainder of the process is known to those of ordinary skill in the art and, therefore, only the process steps and structures necessary to understand the present invention are described herein.

The present invention can be applied to microelectronic devices, such as highly integrated circuit semiconductor devices, processors, micro electromechanical (MEM) devices, optoelectronic devices, and display devices. In particular, the present invention is highly useful for devices requiring high-speed characteristics, such as central processing units (CPUs), digital signal processors (DSPs), combinations of a CPU and a DSP, application specific integrated circuits (ASICs), logic devices, and SRAMs.

Herein, an opening exposing a lower interconnection is referred to as a via, and a region where interconnections will be formed is referred to as a trench. Hereinafter, the present invention will be described by way of an example of a via-first dual damascene process. However the present invention is also applicable to other dual damascene processes as well.

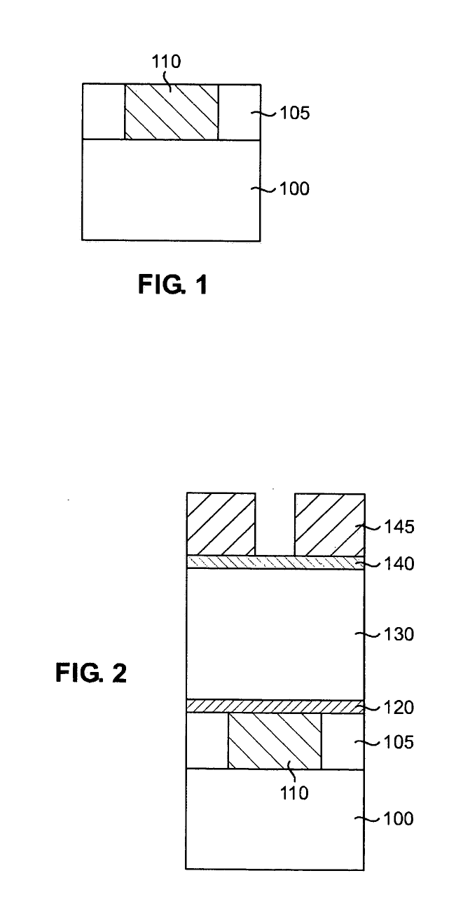

In the present invention the aforementioned problems that can arise when a copper interconnect is formed on a barrier layer that lines the vias and trenches in a dual damascene process is overcome by forming a copper alloy on the barrier layer prior to filling the vias and trenches with bulk copper. A method of fabricating dual damascene interconnections according to an embodiment of the present invention will now be described with reference to FIG. 1 through 9.

As shown in FIG. 1, a substrate 100 is prepared. A lower ILD 105 including a lower interconnection 110 is formed on the substrate 100. The substrate 100 may be, for example, a silicon substrate, a silicon on insulator (SOI) substrate, a gallium arsenic substrate, a silicon germanium substrate, a ceramic substrate, a quartz substrate, or a glass substrate for display. Various active devices and passive devices may be formed on the substrate 100. The lower interconnection 110 may be formed of various interconnection materials, such as copper, copper alloy, aluminium, and aluminium alloy. The lower interconnection 110 is preferably formed of copper because of its low resistance. Also, the surface of the lower interconnection 110 is preferably planarized.

Referring to FIG. 2, an etch stop layer 120, a low-k ILD 130, and a capping layer 140 are sequentially stacked on the surface of the substrate 100 where the lower interconnection 110 is formed, and a photoresist pattern 145 is formed on the capping layer 140 to define a via.

The etch stop layer 120 is formed to prevent electrical properties of the lower interconnection 110 from being damaged during a subsequent etch process for forming a via. Accordingly, the etch stop layer 120 is formed of a material having a high etch selectivity with respect to the ILD 130 formed thereon. Preferably, the etch stop layer 120 is formed of SiC, SiN, or SiCN, having a dielectric constant of 4 to 5. The etch stop layer 120 is as thin as possible in consideration of the dielectric constant of the entire ILD, but thick enough to properly function as an etch stop layer.

The ILD 130 is formed of a hybrid low-k dielectric material, which has advantages of organic and inorganic materials. That is, the ILD 130 is formed of a hybrid low-k dielectric material having low-k characteristics, which can be formed using a conventional apparatus and process, and which is thermally stable. The ILD 130 has a dielectric constant of e.g., 3.3 or less, to prevent an RC delay between the lower interconnection 110 and dual damascene interconnections and minimize cross talk and power consumption. For example, the ILD 130 may be formed of low-k organo silicate glass (OSG) such as Black Diamond™, CORAL™, or a similar material. The ILD 130 can be formed using chemical vapor deposition (CVD), and more specifically, plasma-enhanced CVD (PECVD). The ILD 130 is formed to a thickness of about 3,000 angstroms to 20,000 angstroms or other appropriate thicknesses determined by those skilled in the art.

The capping layer 140 prevents the ILD 130 from being damaged when dual damascene interconnections are planarized using chemical mechanical polishing (CMP). Thus, the capping layer 140 may be formed of SiO₂, SiOF, SiON, SiC, SiN, or SiCN. The capping layer 140 may also function as an anti-reflection layer (ARL) in a subsequent photolithographic process for forming a trench. In this case the capping layer 140 is more preferably formed of SiO₂, SiON, SiC, or SiCN.

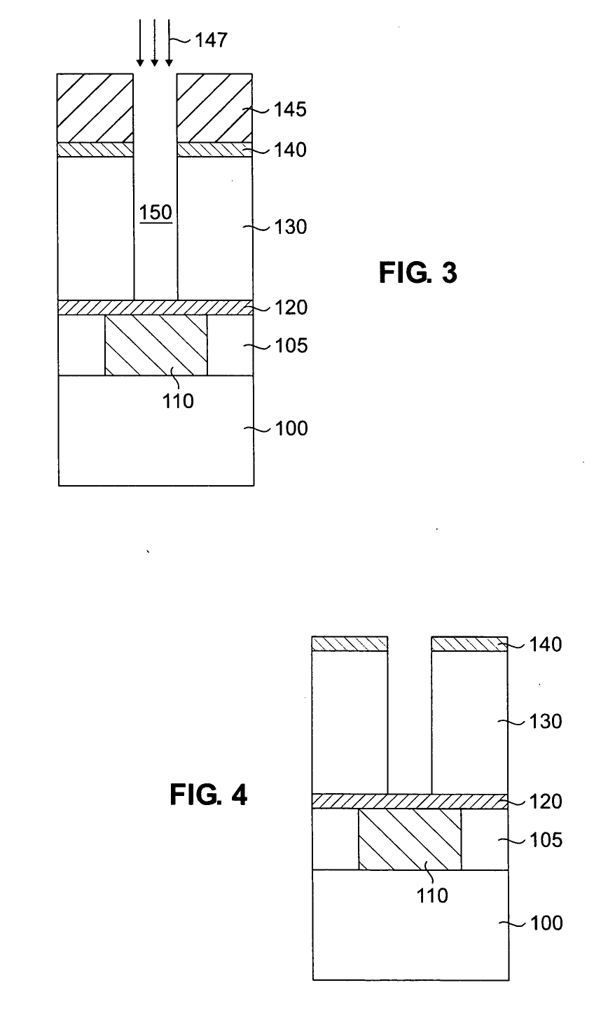

The via photoresist pattern 145 is formed by forming a layer of a photoresist and then performing exposure and developing processes using a photo mask defining a via. Referring to FIG. 3, the ILD 130 is anisotropically etched (147) using the photoresist pattern 145 as an etch mask to form a via 150. The ILD 130 can be etched, for example, using a reactive ion beam etch (RIE) process, which uses a mixture of a main etch gas (e.g., CₓF_{y} and CₓH_{y}F_{z}), an inert gas (e.g. Ar gas), and possibly at least one of O₂, N₂, and COₓ. Here, the RIE conditions are adjusted such that only the ILD 130 is selectively etched and the etch stop layer 120 is not etched.

Referring to FIG. 4, the via photoresist pattern 145 is removed using a stripper. If the photoresist pattern 145 is removed using O₂-ashing, which is widely used for removing a photoresist pattern, the ILD 130, which often contains carbon, may be damaged by the O₂-based plasma. Thus, the photoresist pattern 145 alternatively may removed using an H₂-based plasma.

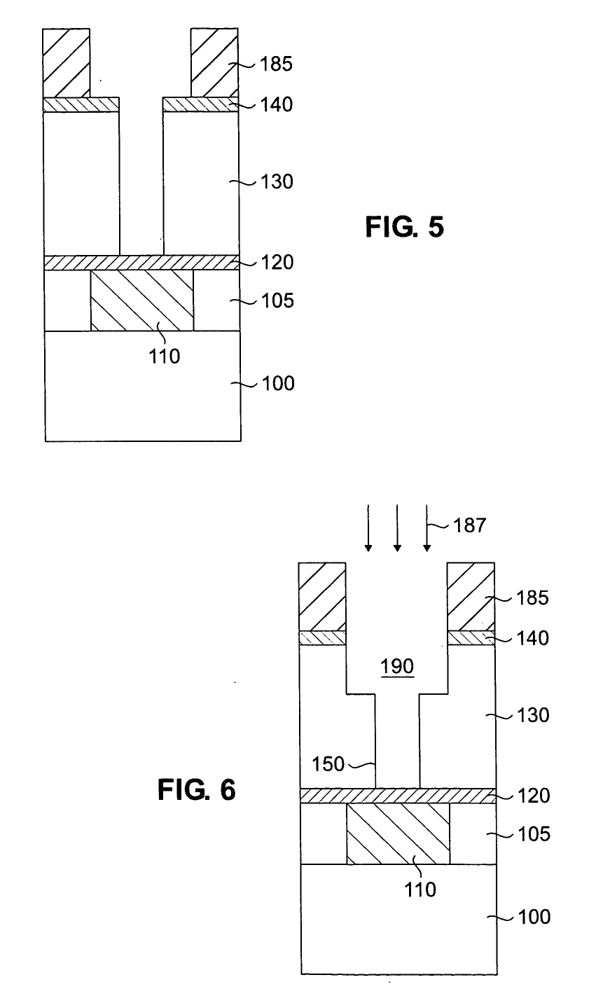

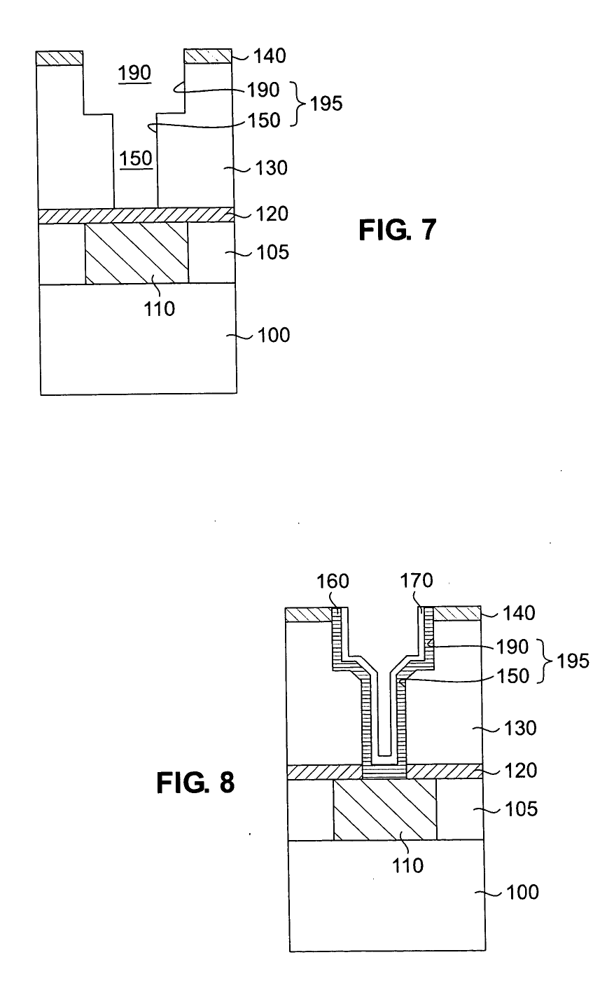

Referring to FIG. 5, a trench photoresist pattern 185 is formed, followed by formation of a trench 190 in FIG. 6. The capping layer 140 is etched using the photoresist pattern 185 as an etch mask, and then the ILD 130 is etched to a predetermined depth to form the trench 190. The resulting structure, shown in FIG. 7, defines a dual damascene interconnection region 195, which includes the via 150 and the trench 190.

Referring to FIG. 8, the etch stop layer 120 exposed in the via 150 is etched until the lower interconnection 110 is exposed, thereby completing the dual damascene interconnection region 195. The etch stop layer 120 is etched so that the lower interconnection 110 is not affected and only the etch stop layer 120 is selectively removed.

A barrier layer 160 is formed on the dual damascene interconnection region 195 to prevent the subsequently formed conductive layer from diffusing into ILD 130. The barrier layer 160 is generally formed from a conventional material such as tantalum, tantalum nitride, titanium, titanium silicide or zircuonium.

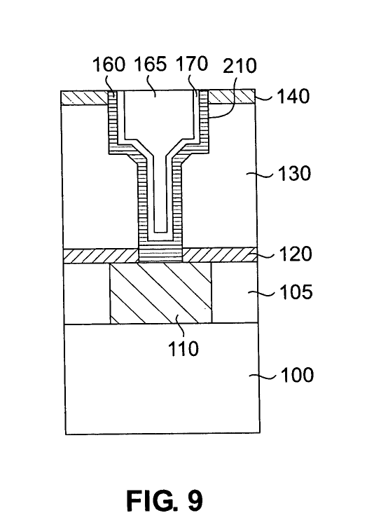

As previously mentioned, after formation of the barrier layer 160, in the conventional process the copper conductive layer is formed on the barrier layer by an electroplating process. However, because of poor adhesion between the copper and the barrier layer, the present invention advantageously first forms a copper alloy layer 170 directly on the barrier layer prior to deposition of the bulk copper. The copper alloy may be formed on the dual damascene interconnection region 195 by a deposition process such as sputtering, for example. The metals that may be combined with copper to form the copper alloy include metals such as Al, Ti, Sn and Ag. In some embodiments of the invention the metal to be alloyed with the copper is directly deposited on barrier layer 160, followed by the formation of the bulk copper layer. An anneal is then performed at an elevated temperature in a known manner to form the copper alloy layer 170 by diffusion of the copper and the metal. Referring to FIG. 9, the bulk copper layer 165 is formed on the dual damascene interconnection region 195 by electroplating and then planarized, thereby forming a dual damascene interconnection 210.

Although various embodiments are specifically illustrated and described herein, it will be appreciated that modifications and variations of the present invention are covered by the above teachings and are within the purview of the appended claims without departing from the spirit and intended scope of the invention. For example, those of ordinary skill in the art will recognize that the via-first dual damascene process described with reference to FIGS. 1 through 9 can be applied to a trench-first dual damascene process.

1. A method of fabricating a dual damascene interconnection, the method comprising:
(a) forming on a substrate a dielectric layer;
(b) forming a via in the dielectric layer;
(c) partially etching the dielectric layer to form a trench, which is connected to the via and in which interconnections will be formed;
(d) forming a barrier layer overlying the via and the trench;
(e) forming a copper alloy layer overlying the barrier layer; and
(f) completing interconnections by filling the trench and the via with copper.

2. The method of claim 1 wherein step (e) includes depositing a metal other than copper on the barrier layer and, after step (f), performing an anneal to thereby form the copper alloy layer by interdiffusion of copper and said metal.

3. The method of claim 2 wherein said metal other than copper is selected from the group consisting of Al, Ti, Sn and Ag.

4. The method of claim 1 wherein said copper alloy is selected from the group consisting of a CuAl alloy, CuTi alloy, CuSn alloy and a CuAg alloy.

5. The method of claim 2 wherein said metal other than copper is deposited by sputtering.

6. The method of claim 3 wherein said metal other than copper is deposited by sputtering.

7. The method of claim 1 wherein the barrier layer is selected from the group consisting of tantalum, tantalum nitride, titanium, titanium silicide or zircuonium.

8. The method of claim 4 wherein the barrier layer is selected from the group consisting of tantalum, tantalum nitride, titanium, titanium silicide or zircuonium.

9. The method of claim 1, further comprising, before step (a): forming a lower interconnection on the substrate; and forming an etch stop layer on the lower interconnection.

10. The method of claim 9, wherein the etch stop layer is formed of at least one of SiC, SiN, and SiCN.

11. The method of claim 1, wherein the dielectric layer is an organo silicate glass layer.

12. The method of claim 1, wherein the dielectric layer is formed using chemical vapor deposition.

13. The method of claim 11, wherein the dielectric layer is formed using chemical vapor deposition.

14. The method of claim 1, further comprising, before step (b), forming a capping layer on the dielectric layer, wherein in step (b), the via is formed in the capping layer and the dielectric layer.

15. The method of claim 14, wherein the capping layer is formed of at least one of SiO₂, SiOF, SiON, SiC, SiN and SiCN.

16. The method of claim 14, wherein step (b) comprises: forming a photoresist pattern on the copper layer to define the via; and dry etching the copper layer and the dielectric layer using the photoresist pattern as an etch mask.

17. The method of claim 1, wherein step (c) includes: forming a trench photoresist pattern over the dielectric layer to define the trench; forming the trench by dry etching using the trench photoresist pattern as an etch mask.

18. The method of claim 14, wherein step (c) includes: forming a trench photoresist pattern over the dielectric layer to define the trench; forming the trench by dry etching using the trench photoresist pattern as an etch mask.

19. The method of claim 18 wherein the trench photoresist pattern in formed on the capping layer.

20. The method of claim 17, wherein the dry etching uses CₓF_{y} or CₓH_{y}F_{z} as a main etching gas, and removing the photoresist pattern uses an H₂-based plasma.

21. The method of claim 1, wherein said dielectric is a hybrid low-k dielectric material.

22. An integrated circuit having at least one dual damascene interconnection constructed in accordance with the method of claim 1.
